(19) United States
(12) Patent Application Publication
(10) Pub. No.: US 2008/0164944 A1
(43) Pub. Date: Jul. 10, 2008

(54) PROTECTION AND AUTOMATIC RECOVERY CIRCUIT SYSTEM

(76) Inventor: Jy-Der David Tai, Phoenix, AZ (US)

Correspondence Address: LEONG C LEI, PMB # 1008, 1867 YGNACIO VALLEY ROAD, WALNUT CREEK, CA, 94598, US

(21) Appl. No.: 11/621,570

(22) Filed: Jan. 10, 2007

(51) Int. Cl. H03F 1/52; H02H 3/06

(52) U.S. Cl. 330/207 P; 361/93.4

(57) ABSTRACT

The circuit system contains an output control circuit, an output stage circuit, a current sensing circuit, and a delay circuit. The output stage circuit is driven by the output control circuit and monitored by the current sensing circuit. When the current sensing circuit determines that there is a short circuit or an abnormal current in the output stage circuit, the current sensing circuit delivers an output signal to disable the output control circuit, which in turn stops the output stage circuit. The output signal is also sent to the delay circuit which, after a period of time, provides a trigger signal to reset the current sensing circuit and to enable the output control circuit again. By providing a large enough delay time, the output stage circuit is able to sustain a very large peak current to prevent it from being damaged.

### TECHNICAL FIELD OF THE INVENTION

The present invention generally relates to the class-D audio power amplifiers, and more particularly to a protection and automatic recovery circuit system for the class-D audio power amplifier.

### DESCRIPTION OF THE PRIOR ART

A power device usually requires a protection circuit so that, when an abnormal load is presented to the output of the power device, the protection circuit is triggered to prevent an excessive large current to damage the power device. The abnormal condition could be temporary or permanent. If it is a permanent abnormality, the problem has to be resolved before the power device is restored for operation.

As to temporary abnormality, some example is commonly found in class-D audio power amplifiers. A class-D audio power amplifier is usually used to drive one or more speakers. Due to the coils used in the speakers, the speakers present not only a resistive load, but also a load with capacitance and inductance. As such, the impedance of the load varies along with the audio signals. Under some circumstance, the load presents a very small impedance, resulting in a very large current which will trigger the protection circuit to shut down the power amplifier. This is especially common for low resistive speakers. As this is usually a temporary abnormality, restarting the power amplifier every time such abnormality occurs is rather inconvenient. However, if the power amplifier is configured to recover by itself and the abnormality still exists for an extended period of time, the protection circuit will be triggered again and the power amplifier will be turned on and off periodically. The result is that a large current pulse train will flow through the power amplifier and eventually the power amplifier will be damaged.

### SUMMARY OF THE INVENTION

A protection and automatic recovery circuit system is provided herein. The circuit system contains an output control circuit, an output stage circuit, a current sensing circuit, and a delay circuit.

The output stage circuit is driven by the output control circuit and monitored by the current sensing circuit. When the current sensing circuit determines that there is a short circuit or an abnormal current in the output stage circuit, the current sensing circuit delivers an output signal to disable the output control circuit, which in turn stops the output stage circuit. The output signal is also sent to the delay circuit which, after a period of time, provides a trigger signal to reset the current sensing circuit and to enable the output control circuit again. By providing a large enough delay time, the output stage circuit is able to sustain a very large peak current to prevent it from being damaged.

The foregoing objectives and summary provide only a brief introduction to the present invention. To fully appreciate these and other objects of the present invention as well as the invention itself, all of which will become apparent to those skilled in the art, the following detailed description of the invention and the claims should be read in conjunction with the accompanying drawings. Throughout the specification and drawings identical reference numerals refer to identical or similar parts.

Many other advantages and features of the present invention will become manifest to those versed in the art upon making reference to the detailed description and the accompanying sheets of drawings in which a preferred structural embodiment incorporating the principles of the present invention is shown by way of illustrative example.

### BRIEF DESCRIPTION OF THE DRAWINGS

FIG. 1 is a functional diagram showing a protection and automatic recovery circuit system according to the present invention.

FIG. 2 is a schematic diagram showing a delay circuit according to an embodiment of the present invention.

FIG. 3 is a waveform diagram showing the signal (S) output by the current sensing circuit if there is no delay circuit configured.

FIG. 4 is a waveform diagram showing the signal (S) output by the current sensing circuit if the delay circuit is in place.

FIG. 5 shows an embodiment of the protection and automatic recovery circuit system according to the present invention.

### DETAILED DESCRIPTION OF THE PREFERRED EMBODIMENTS

The following descriptions are exemplary embodiments only, and are not intended to limit the scope, applicability of configuration of the invention in any way. Rather, the following description provides a convenient illustration for implementing exemplary embodiments of the invention. Various changes to the described embodiments may be made in the function and arrangement of the elements described without departing from the scope of the invention as set forth in the appended claims.

The present invention provides a protection and automatic recovery circuit system applicable to a class-D audio power amplifier. The theory behind the present invention is as follows. The output power of a class-D audio power amplifier can be described the equation below:

Output power=(Vcc×Vcc/R)×D

Vcc is the source of voltage, R is the output load, and D is the duty cycle (=pulse width/pulse period). Usually a circuit can sustain up to a maximum power and, if the limit is exceeded, the circuit would be damaged. Then, based on the foregoing equation, if the current flowing through the circuit is in a pulse train instead of a DC current, the circuit is able to sustain a very large peak current if the duty cycle D is very small.

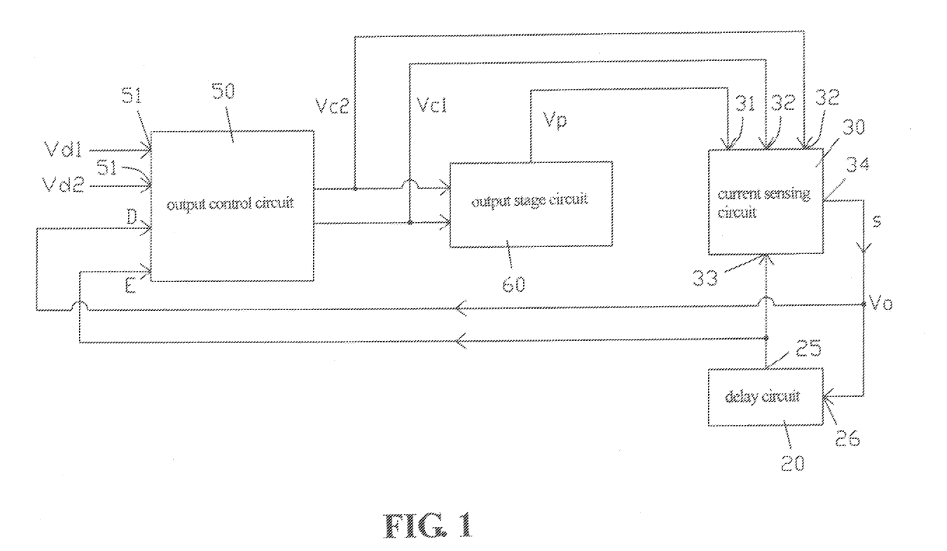

Accordingly, a functional diagram of the circuit system of the present invention is shown in FIG. 1. As illustrated, the circuit system contains an output control circuit 50, an output stage circuit 60, a current sensing circuit 30, and a delay circuit 20.

The output control circuit 50 has a disable (D) terminal and an enable (E) terminal for disabling and enabling the operation of the output control circuit 50, respectively. The output control circuit 50 receives input signals Vd1 and Vd2 from the input terminals 51 and delivers control voltage signals Vc1 and Vc2 to the output stage circuit 60, which in turn provides an output voltage Vp.

The current sensing circuit 30 has a reset terminal 33 for resetting the operation of the current sensing circuit 30. The current sensing circuit 30 receives the control voltage signals Vc1 and Vc2 via the input terminals 32, and the output voltage Vp via another input terminal 31. By examining the signals Vc1, Vc2, and the output voltage Vp to determine if there is a short circuit or an abnormal current, the current sensing circuit 30 delivers an output signal (S) having a voltage Vo via an output terminal 34.

The signal S goes directly to the disable terminal (D) of the output control circuit 50 to shut down the output control circuit 50, which in turn stops the output stage circuit 60, and to the input terminal 26 of the delay circuit 20. After a period of time (during which the output stage circuit 60 remains nonfunctional), the delay circuit 20 provides a trigger signal via its output terminal 25 to the reset terminal 33 of the current sensing circuit 30 and the enable terminal (E) of the output control circuit 50. As such, the output control circuit 50 is operational again while the current sensing circuit 30 starts to monitor for short circuit or abnormal current again.

If the abnormal load or current remains, the current sensing circuit 30 will detect the abnormality and deliver the signal (S) accordingly. Again, the output control circuit 50 and the output stage circuit 60 are shut down for a period of time determined by the delay circuit 20.

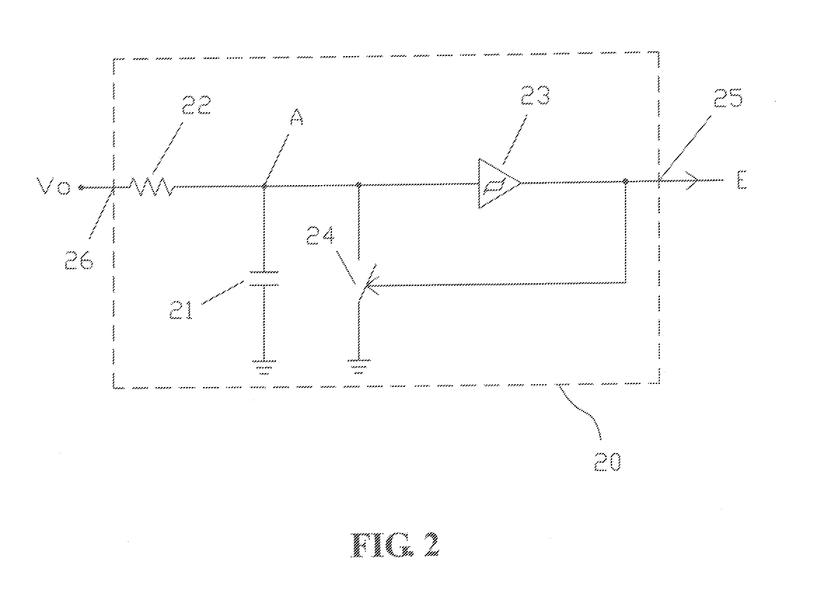

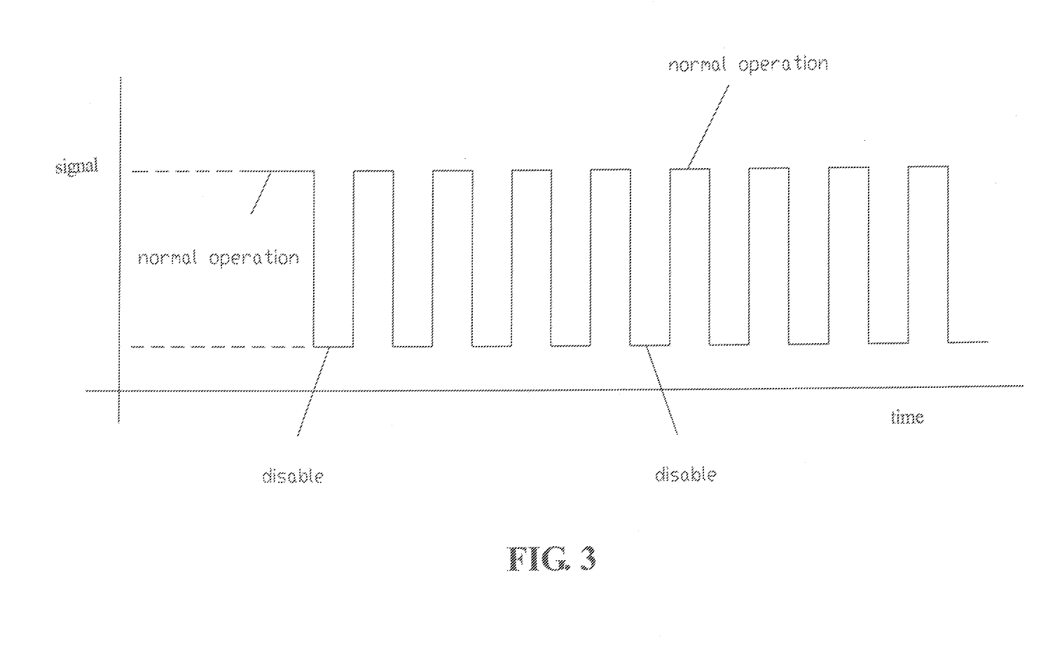

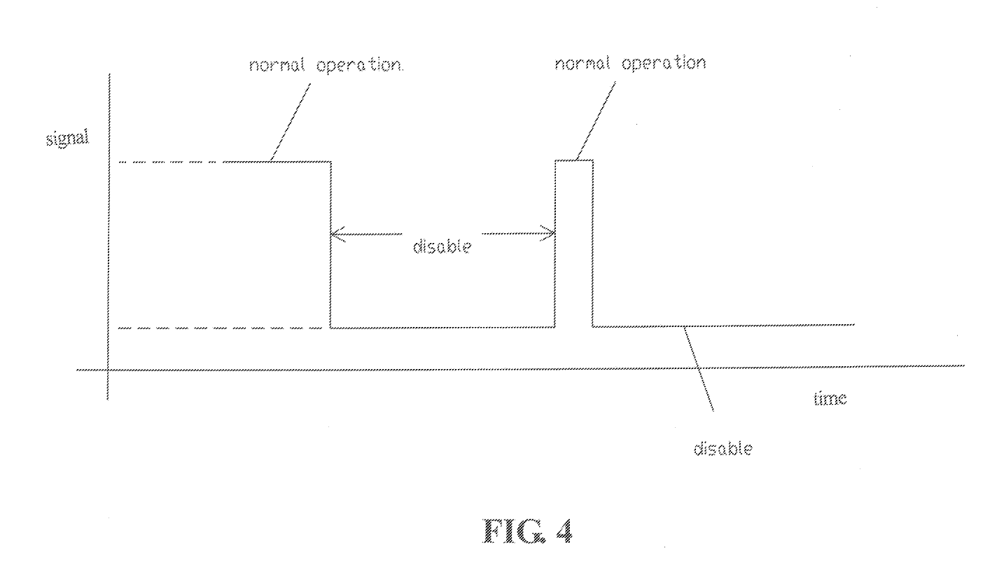

FIG. 3 is a waveform diagram showing the signal (S) versus time (t) output by the current sensing circuit 30 if there is no delay circuit configured. As illustrated, the quick on and off of the signal (S) will continuously result in the abnormal current to flow through the output stage circuit 60. Due to the large duty cycle, the output stage circuit 60 will be damaged quickly. In contrast, FIG. 4 is a waveform diagram showing the signal (S) versus time (t) output by the current sensing circuit 30 if the delay circuit 20 is in place as shown in FIG. 2. As illustrated, due to the configuration of the delay circuit 20, the length of the “disable” time is significantly larger than the“normal operation” time, resulting in a very small duty cycle. As such, the output stage circuit 60 is able to sustain a very large peak current to prevent it or other related circuits being damaged. For a typical class-D amplifier, the current sensing circuit 30 is able to sense the abnormal current in some nano or micro seconds. To make the duty cycle small enough such as less than 0.01 for one micro second sensing time, the delay circuit 20 should offer a delay time at least 100 micro seconds.

FIG. 2 is a schematic diagram showing an embodiment of the delay circuit 20. As illustrated, between the input terminal 26 and the output terminal 25, a resistor 22 and a buffer 23 are series-connected in this order. From between the resistor 22 and the buffer 23, a capacitor 21 is connected to the ground. The resistor 22 and the capacitor 23 jointly form a conventional RC circuit which determines the delay time of the delay circuit 20. The delay circuit 20 also contains a normally-open discharge switch 24 parallel-connected to the capacitor 21.

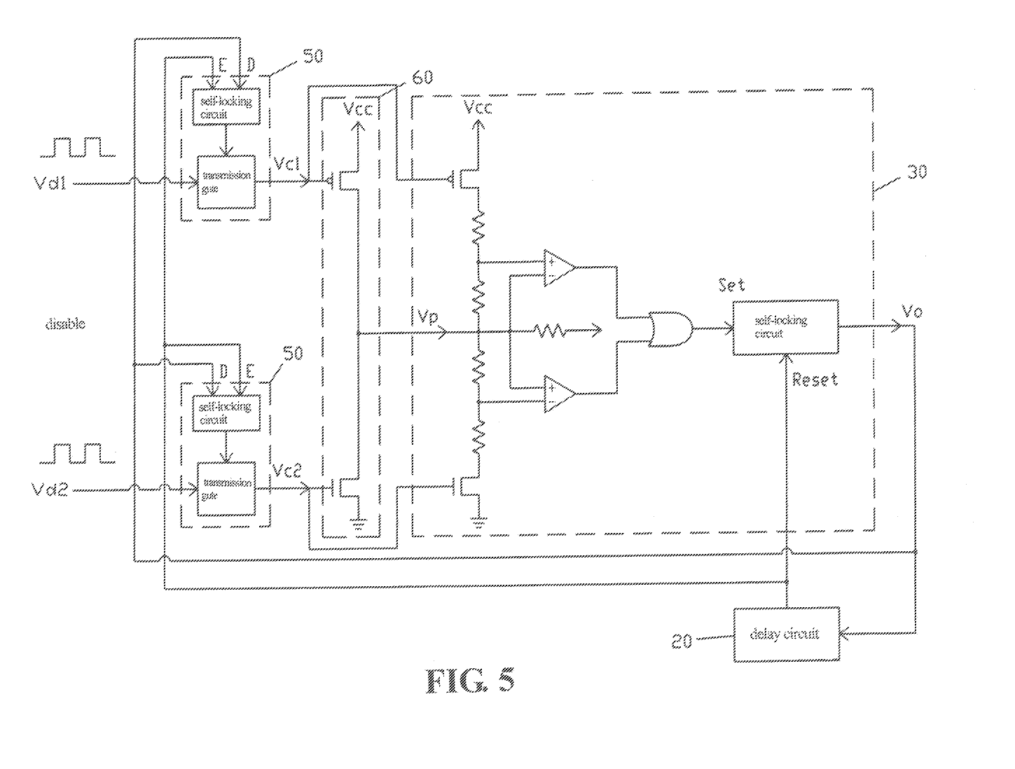

Please further see FIG. 5. When the current sensing circuit 30 detects an abnormal load, the output voltage Vo is raised from a logic low state to a logic high state to disable the output control circuit 50. In the mean time, the output voltage Vo starts to charge the capacitor 21 of the delay circuit 20. When the voltage at point A in FIG. 2 reaches a high threshold voltage of the buffer 23, the buffer 23 outputs a logic high voltage to reset the current sensing circuit 30 so that its output voltage Vo is reset to the logic low state. As such, the output control circuit 50 is functional again as a logic low voltage is at the disable terminal and a logic high voltage is at the enable terminal. The logic high voltage from the buffer 23 also closes the discharge switch 24 to discharge the capacitor 21. When the voltage at point A is dropped to a low threshold voltage, the buffer 23 outputs a logic low voltage to release its trigger to the output control circuit 50 and the current sensing circuit 30. The discharge switch 24 is opened again by the logic low voltage.

As the capacitor 21 is quickly discharged, the delay circuit 20 becomes ready almost immediately to work with the output control circuit 50 and the current sensing circuit 30 when they are enabled and reset to perform normal operation.

As described above, the circuit system is able to recover itself without manual restarting and, by extending the delay time to reduce the duty cycle of the output current, the output stage circuit 60 is able to sustain a much higher peak current.

It will be understood that each of the elements described above, or two or more together may also find a useful application in other types of methods differing from the type described above.

While certain novel features of this invention have been shown and described and are pointed out in the annexed claim, it is not intended to be limited to the details above, since it will be understood that various omissions, modifications, substitutions and changes in the forms and details of the device illustrated and in its operation can be made by those skilled in the art without departing in any way from the spirit of the present invention.

I claim:

1. A protection and automatic recover circuit system comprising:
an output control circuit having an enable terminal and a disable terminal, which receives at least an input signal and produce at least a control signal;
an output stage circuit receiving said control signal and producing an output voltage;
a current sensing circuit having a reset terminal, receiving said control signal of said output control circuit and said output voltage of said output stage circuit, and delivering an output signal to said disable terminal of said output control circuit when an abnormality is detected; and
a delay circuit receiving said output signal of said current sensing circuit via an input terminal and after a period of time producing a trigger signal via an output terminal to said reset terminal of said current sensing circuit and said enable terminal of said output control circuit.

2. The circuit system according to claim 1, wherein said delay circuit comprising:
a resistor rand a buffer series-connected in this order from said input terminal to said output terminal of said delay circuit;
a capacitor connected to the ground from between said resistor and said buffer; and
a normally-open discharge switch parallel-connected to said capacitor, said discharge switch being controlled by said trigger signal.

3. The circuit system according to claim 1, wherein said circuit system is used in a class-D audio power amplifier.
